(19) United States
(12) Patent Application Publication
(10) Pub. No.: US 2024/0071749 A1
(43) Pub. Date: Feb. 29, 2024

(54) SUBSTRATE PROCESSING METHOD

(71) Applicant: ASM IP Holding B.V., Almere (NL)

(72) Inventors: SangHeon Yong, Yongin-si (KR); HongSuk Kim, Yongin-si (KR); SungHa Choi, Suwon-si (KR); JuHyuk Park, Hwaseong-si (KR); KiHun Kim, Yongin-si (KR)

(21) Appl. No.: 18/236,504

(22) Filed: Aug. 22, 2023

Related U.S. Application Data
(60) Provisional application No. 63/400,820, filed on Aug. 25, 2022.

(51) Int. Cl. H01L 21/02; C23C 16/04; C23C 16/34; C23C 16/505

(52) U.S. Cl. CPC H01L 21/0228; C23C 16/045; C23C 16/345; C23C 16/505; H01L 21/0217; H01L 21/02211

(57) ABSTRACT

A method of processing a substrate is disclosed, the method including: providing a substrate to a reaction space, the substrate having at least two gaps on a surface of the substrate, and depositing a flowable film in the at least two gaps while supplying a precursor and a reactant gas into the reaction space, wherein the depositing is discontinuously performed while a pumping operation for the reaction space is continuously maintained.

### CROSS-REFERENCE TO RELATED APPLICATIONS

This application claims priority to U.S. Provisional Patent Application Ser. No. 63/400,820 filed Aug. 25, 2022 titled SUBSTRATE PROCESSING METHOD, the disclosure of which is hereby incorporated by reference in its entirety.

### BACKGROUND

### 1. Field

The present disclosure relates to a substrate processing method, and more particularly, to a substrate processing method for forming a flowable film on a substrate where various pattern structures are formed thereon.

### 2. Description of the Related Art

A gap-fill process is widely used in a semiconductor manufacturing process and refers to a filling process for filling a gap in a pattern structure, such as a shallow trench isolation (STI), with, for example, an insulating material. On the other hand, as the degree of integration of semiconductor devices increases, an aspect ratio (A/R) of the gap in the pattern structure also increases significantly, and accordingly, it has been required to fast fill the gap having a high A/R without the occurrence of voids. In order to fast fill the gap having a high A/R without the occurrence of voids according to this requirement, a technique using a flowable film as a filling material is known.

On the other hand, surface pattern structures of the substrate vertically stacked in each step of the semiconductor manufacturing process take various shapes. That is, the pattern structures exposed over the entire surface of the substrate have various heights vertically and various widths horizontally, and also have critical dimensions (CD) in various sizes, which indicates the minimum line width between the pattern structures. When the flowable film is formed on the substrate where pattern structures having various CD sizes are formed on the surface thereof, the flowable properties of the flowable film formed between the pattern structures or in a gap between the pattern structures also vary depending on the CD size. Due to this, the formation process of the flowable film becomes unstable, and the characteristics and dimensions of the flowable film formed between the pattern structures may be also non-uniform, depending on the CD size of the pattern structure.

Accordingly, when the flowable film is formed on the surface of the substrate, there is a need for a substrate processing method that may stably perform a flowable film formation process even when pattern structures having various CD sizes are formed on the surface of the substrate.

### SUMMARY

The present disclosure provides a substrate processing method that may fill a gap with a flowable film while improving the filling height uniformity of the flowable film to be formed in the gap in a gap-fill process.

The present disclosure provides a substrate processing method that may shorten the process time by optimizing a target filling height of a flowable film to be filled in a gap in a gap-fill process.

Additional aspects will be set forth in part in the description which follows and, in part, will be apparent from the description, or may be learned by practice of the presented embodiments of the disclosure.

According to an aspect of the present disclosure, there is provided a method of processing a substrate, the method including: providing a substrate to a reaction space, wherein a first gap having a first cross-sectional diameter in a horizontal direction, and a second gap having a second cross-sectional diameter in the horizontal direction are formed on a surface of the substrate, wherein the second cross-sectional diameter is less than the first cross-sectional diameter, and filling the first gap and the second gap with a flowable film while supplying a precursor and a reactant gas to the reaction space. The filling may include steps of supplying the precursor and the reactant gas to the reaction space, and pumping the reaction space, wherein, by repeatedly performing the supplying and the pumping, in order to decrease a height difference between a filling height of the flowable film filled in the first gap and a filling height of the flowable film filled in the second gap, a rate of increase of the filling height of the flowable film in the first gap may increase relatively, and at the same time, the rate of increase of the filling height of the flowable film in the second gap may decrease relatively.

In some embodiments, in the pumping the reaction space, the supply of the precursor and the reactant gas may be blocked, and the supply of RF power applied to the reaction space may be blocked. In some embodiments, the reaction space may be continuously pumped even in the supplying the precursor and the reactant gas.

In some embodiments, a ratio of a period of the supplying the precursor and the reactant gas to a period of the pumping the reaction space may be in a range between about 1:5 to about 5:1.

In some embodiments, by repeatedly performing the supplying and the pumping, in order to decrease a difference between a filling speed of the flowable film filled in the first gap and a filling speed of the flowable film filled in the second gap, the filling speed of the flowable film in the first gap may increase relatively, and at the same time, the filling speed of the flowable film in the second gap may decrease relatively.

In some embodiments, a vertical depth of the first gap may be substantially the same as a vertical depth of the second gap, and an internal volume of the first gap may be greater than an internal volume of the second gap. In some embodiments, a vertical depth of the first gap may be different from a vertical depth of the second gap, and an internal volume of the first gap may be greater than an internal volume of the second gap.

In some embodiments, a pressure within the reaction space in the supplying the precursor and the reactant gas may be in a range of about 1 Torr to about 10 Torr, and the pressure within the reaction space in the pumping may be less than or equal to about 3 Torr. In some embodiments, the pumping may be performed to decrease a difference between a partial pressure in the first gap and a partial pressure in the second gap.

In some embodiments, the filling may be performed at a process temperature between about 0° C. and about 150° C.

In some embodiments, the precursor supplied to the reaction space may include a silicon-containing precursor and the reactant gas may include a nitrogen-containing gas. In some embodiments, the silicon precursor may include at least one of amino-silane series, iodosilane series, silicon halide series, and oligomer Si source, or at least one of mixtures thereof.

In some embodiments, the silicon precursor may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂ (NEt₂)₂; BDMAS, SiH₂ (NMe₂)₂; BTBAS, SiH₂ (NHtBu)₂; BITS, SiH₂ (NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂ (NHEt)₆; TEAS, Si(NHEt)₄; Si₃H₈; DCS, SiH₂Cl₂; SiHl₃; SiH₂I₂; Dimer-trisilylamine; Trimer-trisilylamine; Tetramer-trisilylamine; Pentamer-trisilylamine; Hexamer-trisilylamine; Heptamer-trisilylamine; and Octamer-trisilylamine, or at least one of derivatives thereof or mixtures thereof.

According to an aspect of the present disclosure, there is provided a method of processing a substrate, the method including: providing a substrate to a reaction space, the substrate having at least two gaps on a surface of the substrate, and depositing a flowable film in the at least two gaps while supplying a precursor and a reactant gas to the reaction space, wherein the depositing is discontinuously performed while a pumping operation for the reaction space is continuously maintained.

In some embodiments, during a discontinuous period of the depositing, the supply of the precursor and the reactant gas to the reaction space may be blocked, and the supply of RF power applied to the reaction space may be blocked.

In some embodiments, the at least two gaps may include a first gap having a first cross-sectional diameter in a horizontal direction, and a second gap having a second cross-sectional diameter in the horizontal direction, wherein the second cross-sectional diameter is less than the first cross-sectional diameter, and as the depositing is discontinuously performed, in order to decrease a height difference between a filling height of the flowable film filled in the first gap and a filling height of the flowable film filled in the second gap, a rate of increase of the filling height of the flowable film in the first gap may increase relatively, and at the same time, the rate of increase of the filling height of the flowable film in the second gap may decrease relatively.

In some embodiments, the at least two gaps may include a first gap having a first cross-sectional diameter in a horizontal direction, and a second gap having a second cross-sectional diameter in the horizontal direction, wherein the second cross-sectional diameter is less than the first cross-sectional diameter, and as the depositing is discontinuously performed, in order to decrease a difference between a filling speed of the flowable film filled in the first gap and a filling speed of the flowable film filled in the second gap, the filling speed of the flowable film in the first gap may increase relatively, and at the same time, the filling speed of the flowable film in the second gap may decrease relatively.

In some embodiments, an internal volume of the first gap may be greater than an internal volume of the second gap. In some embodiments, a vertical depth of the first gap may be substantially the same as a vertical depth of the second gap, and an internal volume of the first gap may be greater than an internal volume of the second gap. In some embodiments, a vertical depth of the first gap may be different from a vertical depth of the second gap, and an internal volume of the first gap may be greater than an internal volume of the second gap.

In some embodiments, a pressure within the reaction space in the depositing may be in a range of about 1 Torr to about 10 Torr, and the pressure within the reaction space during a discontinuous period of the depositing may be less than or equal to about 3 Torr. In some embodiments, the filling may be performed at a process temperature between about 0° C. and about 150° C.

In some embodiments, the precursor supplied into the reaction space may include a silicon precursor and the reactant gas may include a nitrogen-containing gas. In some embodiments, the silicon precursor may include at least one of amino-silane series, iodosilane series, silicon halide series, and oligomer Si source, or at least one of mixtures thereof.

According to an aspect of the present disclosure, there is provided a method of processing a substrate, the method including: providing a substrate having at least two gaps formed on a surface of the substrate in a reaction space, wherein the at least two gaps includes a first gap having a first cross-sectional diameter in a horizontal direction, and a second gap having a second cross-sectional diameter in the horizontal direction, wherein the second cross-sectional diameter may be less than the first cross-sectional diameter, depositing a flowable film in the gaps while supplying a precursor and a reactant gas to the reaction space, and performing a pumping operation for the reaction space, wherein the depositing the flowable film and the performing the pumping operation are repeatedly performed in one cycle, and as the number of repetitions of the cycle increases, a difference between a filling speed of the flowable film to be filled in the first gap and a filling speed of the flowable film to be filled in the second gap may decrease.

In some embodiments, in the performing the pumping operation, the supply of the precursor and the reactant gas to the reaction space may be blocked, and the supply of RF power applied to the reaction space may be blocked.

In some embodiments, the depositing the flowable film and the performing the pumping operation may be repeatedly performed in one cycle, and as the number of repetitions of the cycle increases, in order to decrease a height difference between a filling height of the flowable film filled in the first gap and a filling height of the flowable film filled in the second gap, a rate of increase of the filling height of the flowable film in the first gap may increase relatively, and at the same time, the rate of increase of the filling height of the flowable film in the second gap may decrease relatively.

In some embodiments, an internal volume of the first gap may be greater than an internal volume of the second gap.

In some embodiments, a pressure within the reaction space in the depositing the flowable film may be in a range of about 1 Torr to about 10 Torr, and the pressure within the reaction space in the performing the pumping operation may be less than or equal to about 3 Torr.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A to 1D are cross-sectional views conceptually illustrating a process of filling a gap with a flowable film;

FIG. 2 is a diagram illustrating a process sequence of a conventional substrate processing method;

FIGS. 3 to 6 are cross-sectional views illustrating a process of forming a flowable film in a gap, according to the process sequence of FIG. 2;

FIG. 7 is a diagram illustrating a process sequence according to example embodiments of the present disclosure;

FIGS. 8 to 11 are cross-sectional views illustrating a process of forming a flowable film in a gap according to the process sequence of FIG. 7;

FIG. 12A is a transmission electron microscopy (TEM) photograph illustrating a flowable film formed in a gap for a short time according to the process sequence of FIG. 2;

FIG. 12B is a TEM photograph illustrating a flowable film formed in a gap for a long time according to the process sequence of FIG. 2;

FIG. 12C is a TEM photograph illustrating a flowable film formed in a gap according to example embodiments of the present disclosure; and

FIG. 13 is a graph comparing the height of the flowable film formed in a gap for each CD size according to example embodiments of the present disclosure, to that of the prior art.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the present disclosure will be described in detail with reference to the accompanying drawings.

Embodiments of the present disclosure are provided to further explain the present disclosure to one of ordinary skill in the art, and the following embodiments may have different forms and the scope of the present disclosure should not be construed as being limited to the descriptions set forth herein. Rather, these embodiments are provided so that the disclosure will be thorough and complete, and will fully convey the scope of the disclosure to one of ordinary skill in the art.

The terminology used herein is for describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any particular order, upper and lower, or importance, but rather are only used to distinguish one member, region, layer, and/or section from another member, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected because of, for example, manufacturing techniques and/or tolerances. Thus, the embodiments of the disclosure should not be construed as being limited to the particular shapes of regions illustrated herein but may include deviations in shapes that result, for example, from manufacturing processes.

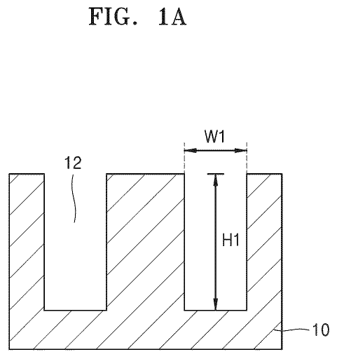

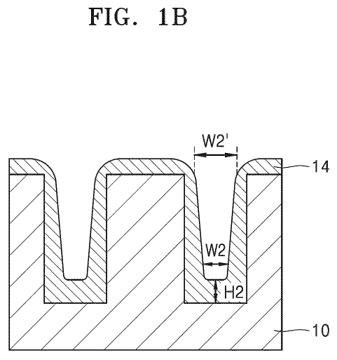

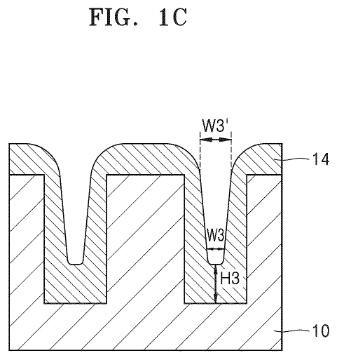

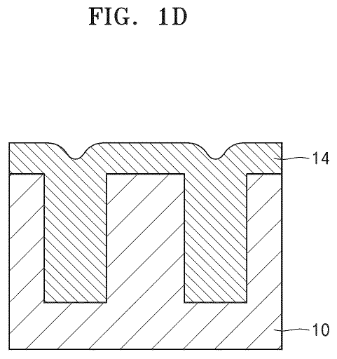

First, according to a flowable chemical vapor deposition method, a substrate processing method of performing a gap-fill process to fill a gap on a substrate with a flowable film, for example, a silicon nitride film, is described. FIGS. 1A to 1D are cross-sectional views conceptually illustrating a general process of filling a gap with a flowable film.

Referring to FIG. 1A, a substrate 10 provided in a reaction space (not shown) in which a gap-fill process is performed is shown. On a part of a surface of the substrate 10, a gap structure including gaps 12 that may have a certain vertical depth H1 in a vertical direction and a certain horizontal width W1 in a horizontal direction is shown. FIG. 1A shows that a plurality of gaps 12 formed on a surface of the substrate 10 have the same width W1 in the horizontal direction, for example. In addition, FIG. 1A shows that a plurality of gaps 12 formed on the surface of the substrate 10 have the same depth H1 in the vertical direction, for example.

Referring to FIG. 1B, when RF power is applied to the reaction space while supplying a precursor, for example, a silicon precursor, and a reactant gas to the reaction space, the reaction space may become a plasma atmosphere, and under the plasma atmosphere, a flowable film 14, such as a silicon nitride, may be deposited on an exposed surface of the substrate 10 with the gap 12, through a condensation reaction, an oligomerization reaction, a polymerization reaction, etc. between the silicon precursor and the reactant gas. The flowable properties of flowable film 14 may cause the flowable film 14 to flow down from the upper region of the gap 12 to the lower region of the gap 12, thereby depositing the flowable film 14 in the gap 12, and accordingly, in the width of the inner space between the flowable films 14 to be formed in the gap 12, a width W2 in the lower region becomes less than a width W2′ in the upper region of the gap 12. As described above, since a plurality of gaps formed on the surface of the substrate 10 may have the same width W1 in the horizontal direction and the same depth H1 in the vertical direction of the gap 12, the flowable film 14 may be generally formed in the gap 12 at the same filling speed with the same shape.

Referring to FIG. 1C, as the gap-fill process further proceeds, since the flowable film 14 is deposited in the gap 12 while the flowable film 14 flows down from the upper region of the gap 12 to the lower region of the gap 12, in the width of the inner space between the flowable films 14 to be deposited in the gap 12, a width W3 in the lower region thereof may become less than a width W3′ in the upper region of the gap 12 and the height of the flowable film 14 formed upward from the bottom surface of the gap 12 may also increase (i.e., from H2 to H3).

Referring to FIG. 1D, as the gap-fill process further proceeds and sufficient time passes, the gap 12 may be completely filled with the flowable film 14 without the occurrence of voids inside the gap.

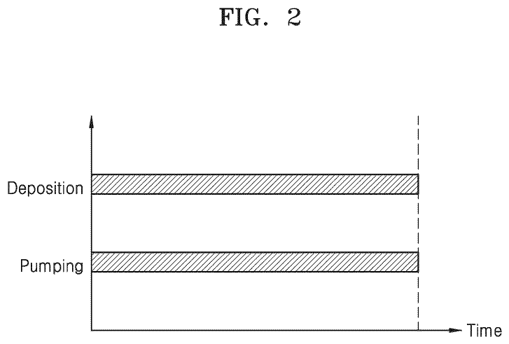

FIG. 2 is a diagram illustrating a process sequence of a conventional substrate processing method. FIGS. 1A to 1D show an example of the gap-fill process of a flowable film according to the process sequence of FIG. 2.

Referring to FIG. 2 with FIGS. 1A to 1D, after the substrate 10 is provided to the reaction space (not shown) in which the gap-fill process may be performed, when the RF power is applied to the reaction space while supplying process gases, such as the silicon precursor and the reactant gas, to the reaction space, the reaction space may become plasma atmosphere, and therefore, the flowable film 14 may be deposited on the exposed surface of the substrate having the gap 12, through a condensation reaction, an oligomerization reaction, and a polymerization reaction between the silicon precursor and the reactant gas.

On the other hand, during the deposition of the flowable film 14, an excess of the silicon precursor and the reactant gas to be supplied to the reaction space, reaction byproducts, carrier gases involved in transporting process-related gases, or a purge gas, etc. may be discharged to the outside through a continuous pumping operation (or exhaust operation), through an exhaust pump connected to the reaction space. Pressure within the reaction space may be maintained within a specific range according to the needs of the process conditions, through the pumping operation (or exhaust operation) for the reaction space.

Therefore, while keeping the pumping operation for the reaction space, the gap-fill process may be completed as the flowable film 14 is continuously deposited on the exposed surface of the substrate having the gap 12, under the plasma atmosphere in the reaction space.

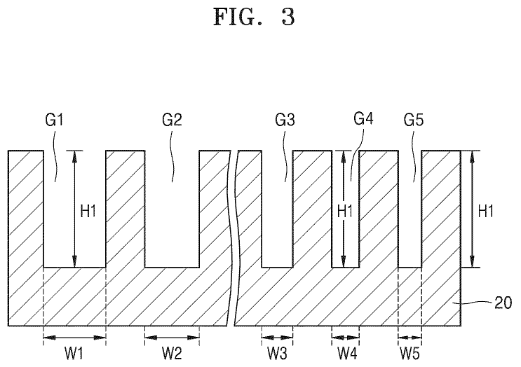

FIGS. 3 to 6 are cross-sectional views illustrating a process of forming a flowable film in a gap, according to the process sequence of FIG. 2. FIGS. 1A to 1D show a process of filling the flowable film 14 in the gaps 12 when a plurality of gaps 12 having the same shapes, that is, the same width W1 in the horizontal direction and the same depth H1 in the vertical direction, are formed on the surface of the substrate 10. On the other hand, FIGS. 3 to 6 show the process of filling a flowable film in gaps when gaps of various shapes are formed on the surface of a substrate.

Referring to FIG. 3, a substrate 20 provided to a reaction space (not shown) in which the gap-fill process may be performed is shown. Semiconductor integrated circuits may have various pattern structures and shapes vertically in the manufacturing process thereof. These pattern structures which may be formed of semiconductor layers, conductive layers, and/or insulating layers, and various electrical circuits may be configured by vertically stacking the pattern structures in various ways. The surface of the substrate may have various pattern structures in each step of the manufacturing process of semiconductor integrated circuits, and FIG. 3 shows a gap structure among various pattern structures, in which for example, each gap G1-G5 has the same depth H1 in the vertical direction, but has different widths W1, W2, W3, W4, and W5 in the horizontal direction.

In FIG. 3, the order of the size of widths thereof in the horizontal direction may be W1>W2>W2>W4>W5, and the widths thereof in the horizontal direction may decrease from the gap G1 to the gap G5. In addition, each gap G1-G5 is assumed to have the same shape. For example, each gap G1-G5 is assumed to be a cylindrical gap in which each gap G1-G5 may have the same vertical depth H1, a cross-section thereof in the horizontal direction may have a circular shape, each gap may have a vertical profile in which side walls thereof may be perpendicular to the horizontal plane, and it is also assumed that in each gap G1-G5 only the widths in the horizontal direction, for example, cross-sectional diameters in the horizontal direction, may decrease from the gap G1 to the gap G5. Thus, based on such assumptions, the internal volume of each gap G1-G5 may also decrease from the gap G1 to the gap G5.

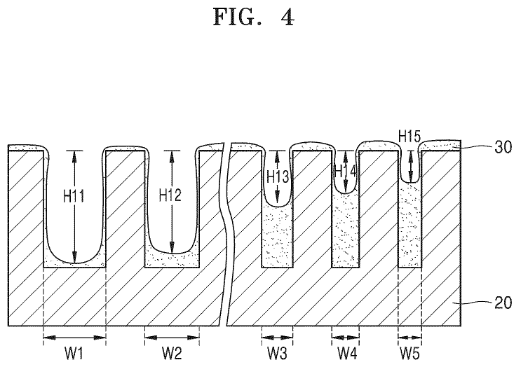

Referring to FIG. 4, the gap-fill process may proceed to deposit a flowable film 30 on the surface of the substrate 20 shown in FIG. 3. Specifically, when the RF power is applied to the reaction space while supplying the silicon precursor and the reactant gas to the reaction space, the reaction space may become plasma atmosphere, and under the plasma atmosphere, the flowable film 30, such as silicon nitride, may be deposited on an exposed surface of the substrate 20 having the gaps G1-G5, through a condensation reaction, an oligomerization reaction, a polymerization reaction, etc. between the silicon precursor and the reactant gas. Due to the flowable properties of the flowable film 30, the flowable film 30 may be formed by flowing down along the side walls of the gaps G1-G5 from the upper region of the gaps G1-G5 to the lower region thereof.

Comparing FIG. 4 to FIG. 1B described above, since in FIG. 1B, the gaps 12 of the same shape are formed on the surface of the substrate 10, the flowable film 14 formed on the exposed surface of the substrate 10 may be formed while having the same flowable properties and having the same shape, however, since in FIG. 4, the gaps G1-G5 of different shapes are formed on the surface of the substrate 20, the flowable film 30 formed on the exposed surface of the substrate 20 may be formed in different shapes for each gap G1-G5.

Specifically, as shown in FIG. 4, filling speeds of the flowable film 30 formed in the gaps G1-G5 according to widths of the gap, for example, cross-sectional diameters of the gaps, may be different. That is, as the cross-sectional diameter of the gap decreases, the influence of the capillary phenomenon may increase, and thus, the filling speed, for example, a filling rate for filling the gap with the flowable film 30, for example, in volume, may increase. In addition, as the cross-sectional diameter of the gap decreases, the influence of the capillary phenomenon may increase, and thus, a filling height of the flowable film 30 deposited upward from the bottom surface of the gaps G1-G5, may increase. Referring to FIGS. 3 and 4, the filling heights of the flowable film 30 to be filled in the gaps G1-G5 may be values obtained by subtracting depths H11, H12, H13, H14, and H15 of unfilled portions that are not filled with the flowable film 30, respectively, from the vertical depths H1 of the gaps G1-G5 before the flowable film 30 is filled. Therefore, as the widths of the gaps decrease from the gap G1 to the gap G5 (i.e., W1>W2>W3>W4>W5), the depths of the unfilled portions may also decrease (i.e., H11>H12>H13>H14>H15).

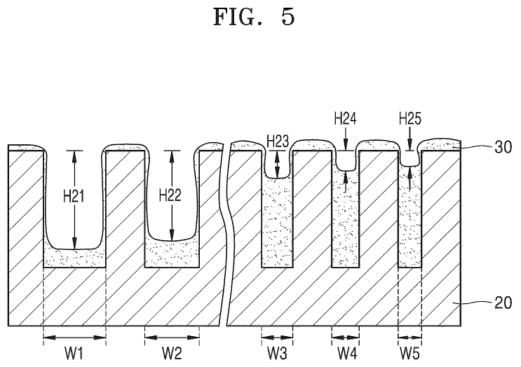

Referring to FIG. 5, as the gap-fill process further proceeds, the flowable film 30 may be continuously deposited on the surface of the substrate 20. As a deposition process for the flowable film 30 proceeds, due to the flowable properties of the flowable film 30, the flowable film 30 may be formed upwardly in the gaps G1-G5 while flowing down along the side walls of the gaps G1-G5 from the upper region of the gaps G1-G5 to the lower region thereof. At this time, as shown in FIG. 5, as the cross-sectional diameters of the gaps decrease, the influence of the capillary phenomenon may increase, so that the filling speed of the flowable film 30 formed in the gaps G1-G5 may also increase. Alternatively, as the cross-sectional diameter of the gap decreases, the filling height of the flowable film 30 to be deposited from the bottom surface of the gaps G1-G5 may increase. Specifically, with reference to FIGS. 4 and 5, the filling height of the flowable film 30 in the gap G1 has increased by a height corresponding to the difference in the vertical height between the unfilled portions in the gap G1, that is, (H11-H21). On the other hand, the filling height of the flowable film 30 in the gap G5 has increased by a height corresponding to the difference in the vertical height between the unfilled portions in the gap G5, that is, (H15-H25). Here, due to the influence of the capillary phenomenon, the rate of increase in the filling height of the flowable film 30 in the gap G5 may be increased more compared to the gap G1 (i.e., (H15-H25)>(H11-H21). As a result, as the gap-fill process of the flowable film 30 proceeds with respect to the substrate 20 having gaps with various cross-sectional diameters formed on the surface thereof, the smaller the cross-sectional diameter of the gap, the faster the gap may be filled.

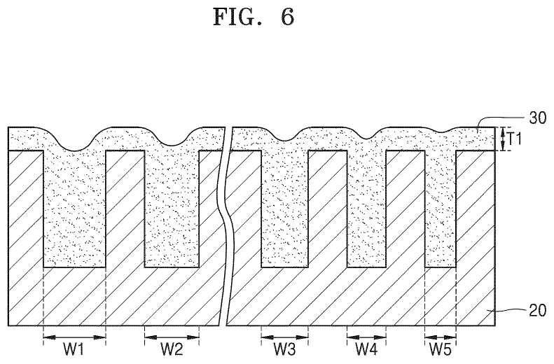

Referring to FIG. 6, the gap-fill process may further proceed to terminate the deposition process of the flowable film 30. The deposition process of the flowable film 30 may be terminated based on the gap in which the flowable film 30 is filled at least last, for example. In FIG. 6, for example, when the flowable film 30 fully fills the gap G1 that has the largest width of a gap (i.e., the largest cross-sectional diameter), the deposition process may be terminated as the rate of increase of the filling height may be the slowest in the gap G1. Therefore, since the deposition process of the flowable film 30 may continue until the filling of the flowable film 30 in the gap G1 is fully completed, as the width of the gap becomes smaller from G1 to G5 and the filling speed becomes higher from G1 to G5 accordingly, the flowable film 30 may be over-deposited in the gap, for example, by a portion corresponding to a thickness T1.

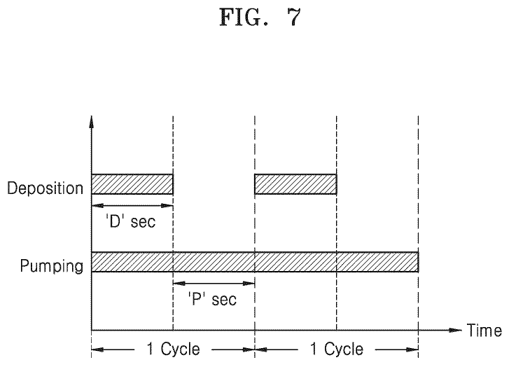

FIG. 7 is a diagram illustrating a process sequence according to example embodiments of the present disclosure. Compared to FIG. 2, which shows the process sequence of the conventional substrate processing method, the process sequence of FIG. 7 is different in that the pumping operation (or the exhaust operation) for the reaction space may be performed continuously when the gap-fill process is performed with the flowable film, however, the deposition step of the flowable film may be discontinuously performed. From another point of view, in the process sequence according to example embodiments of the present disclosure invention, as shown in FIG. 7, for example, a deposition step during a period ‘D’ seconds and a pumping step during a period ‘P’ seconds may be in one cycle, and the cycle may be repeatedly performed a plurality of times.

Specifically, referring to FIG. 7, in the deposition step, after the substrate is provided to the reaction space (not shown) in which the gap-fill process may be performed, when RF power is applied to the reaction space while supplying process gases, such as the silicon precursor and the reactant gas, to the reaction space, the reaction space may become plasma atmosphere, and therefore, the flowable film may be deposited on the exposed surface of the substrate having the gap, through a condensation reaction, an oligomerization reaction, and a polymerization reaction between the silicon precursor and the reactant gas. According to example embodiments of the present disclosure, the precursor and the reactant gas may not be supplied continuously to the reaction space. For example, the precursor and the reactant gas may be supplied for a certain period (e.g., during ‘D’ seconds), the supply of the precursor and the reactant gas may be blocked for a certain period (e.g., ‘P’ seconds), and then, the precursor and the reactant gas may be again supplied to the reaction space. That is, the supply of the silicon precursor and the reactant gas to the reaction space may occur intermittently or discontinuously. In other words, the deposition step may be divided into a supply step and a blocking step of the process gases. In the supply step, the flowable film may be substantially deposited while the plasma is generated in the reaction space by applying the RF power to the reaction space with the supply of the precursor and the reactant gases. The blocking step may be a step in which both the supply of the precursor and the reactant gases and the supply of the RF power may be blocked and only the pumping operation may persist, among the entire deposition process, and may be referred to as a pumping step.

On the other hand, in the pumping step, during the deposition of the flowable film, an excess of the silicon precursor and the reactant gas to be supplied to the reaction space, reaction byproducts, carrier gases involved in transporting process-related gases, or a purge gas, etc. may be discharged to the outside through a continuous pumping operation through an exhaust pump connected to the reaction space. The pressure in the reaction space may be maintained within a specific range, through the pumping operation (or exhaust operation) for the reaction space. On the other hand, the intensity of the pumping operation may be adjusted to increase or decrease the pressure in the reaction space according to the needs of the process conditions. For example, the pumping operation may continue in the entire process of the deposition step, regardless of the above-described supply step and blocking step (or pumping step). In some embodiments, the intensity of the pumping operation may be the same in both the supply step and the pumping step, but in other embodiments, the intensity of the pumping operation may be adjusted to increase or decrease the pressure within the reaction space in the pumping step depending on the needs of the process conditions.

The process conditions for the process sequence of FIG. 7 are summarized in Table 1 below.

TABLE 1

| Process Variable | Deposition Step | Pumping Step |
|---|---|---|
| Time (sec) | 1-1800 | 1-1800 |
| Pressure (Torr) | 1-10 | ≤3 |
| Process gas injection | On | — |
| RF Power (W) | 50-1000 | — |
| Temperature (° C.) | <150 | <150 |

In example embodiments of the present disclosure, a ratio of the period of the supply step of the precursor and the reactant gas (e.g., the deposition step) to the period of the pumping step for the reaction space may be in a range of about 1:5 to about 5:1. In some embodiments, the period of the deposition step may be longer or shorter than the period of the pumping step. In some embodiments, the pressure of the reaction space in the supply step of the precursor and the reactant gas may be in a range of about 1 Torr to about 10 Torr, and the pressure of the reaction space in the pumping step may be greater than 0 Torr and less than or equal to about 3 Torr. In some embodiments, the deposition step may be performed at a process temperature between about 0° C. and about 150° C.

The process sequence according to FIG. 7 will be described by applying specifically to example embodiments of the present disclosure.

First, a case in which the process sequence according to FIG. 7 is applied to the gap-fill process of FIGS. 1A to 1D will be described.

As shown in FIG. 1A, the process sequence of FIG. 7 may be used for the gap structure having a plurality of gaps 12 of the same shape with the depth H1 in the vertical direction and the width W1 in the horizontal direction in some regions of the surface of the substrate 10. In this case, when the plurality of gaps 12 have the same shape, for example, the same cross-sectional diameters thereof, or the same volumes thereof, the flowable properties of the flowable film 14 formed in each gap 12 may be considered to be substantially the same.

Therefore, in each gap 12, the flowable film 14 may be formed in the same filling height. In addition, each gap may be fully filled with the flowable film 14 while maintaining the same filling speed, such as the same filling rate, without the occurrence of voids in the gap.

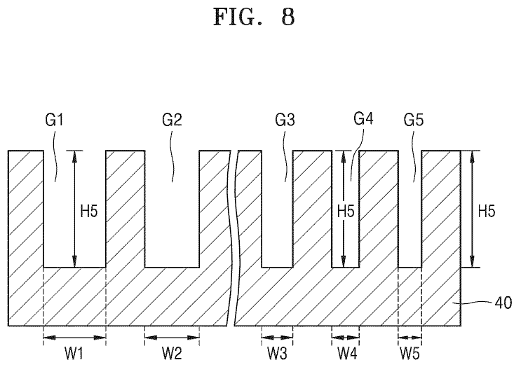

Next, a case in which the process sequence according to FIG. 7 is applied to the gap-fill process of FIGS. 8 to 11 will be described. FIGS. 1A to 1D described above show a process of filling the flowable film 14 in the gaps 12 when a plurality of gaps 12 having the same shapes, that is, the same width W1 in the horizontal direction and the same depth H1 in the vertical direction, are formed on the surface of the substrate 10. On the other hand, FIGS. 3 to 6 are distinguished from FIGS. 1A to 1D in that FIGS. 3 to 6 show the process of filling a flowable film in gaps when gaps of various shapes are formed on the surface of the substrate.

Referring to FIG. 8, a substrate 40 provided to a reaction space (not shown) in which the gap-fill process may be performed is shown. Semiconductor integrated circuits may have various pattern structures and shapes vertically in the manufacturing process thereof. These pattern structures may be formed of semiconductor layers, conductive layers, and/or insulating layers, and these pattern structures may be stacked vertically in various ways to form electrical circuits. Therefore, in each step of the manufacturing of semiconductor integrated circuits, the surface of the substrate may have various pattern structures, and FIG. 8 schematically shows a gap structure among the various pattern structures. For example, FIG. 8 shows that each gap G1 to G5 may have vertically the same depth H5, but may have different widths W1, W2, W3, W4, and W5 in the horizontal direction. Actually, the pattern structures that are vertically stacked in the manufacturing process of semiconductor integrated circuits may have various shapes. In particular, among the various pattern structures, the gaps may have various shapes in the width in the horizontal direction, the depth in the vertical direction, the volume inside the gap, the vertical profile of the sidewall of the gap, and the surface cross-section of the gap, etc.. In this embodiment, for the convenience of explanation and to facilitate understanding of the present disclosure, a case in which the gap-fill process of the present disclosure is used for the plurality of gaps having the same vertical depths but having various horizontal widths will be described.

In FIG. 8, the widths of the gaps G1-G5 in the horizontal direction are in the order of W1>W2>W3>W4>W5, and the widths thereof in the horizontal direction may decrease from the gap G1 to the gap G5. In addition, each gap G1-G5 may be assumed to have the same shape, for example, a cylindrical shape. That is, as shown in FIG. 8, each gap G1-G5 is assumed to have the same vertical depth H1, a cross-section of a circular shape in the horizontal direction, and a vertical profile perpendicular to the horizontal plane, and it is also assumed that in each gap G1-G5 only the widths in the horizontal direction, for example, cross-sectional diameters in the horizontal direction, may decrease from the gap G1 to the gap G5. Based on such assumptions, the internal volume of each gap G1-G5 may also decrease from the gap G1 to the gap G5.

Referring to FIG. 8, the substrate 40 may include semiconductor materials, such as Si or Ge, or various compound semiconductor materials, such as SiGe, SiC, GaAs, InAs, and InP, and may include various substrates to be used in a display device or a semiconductor device, etc., such as silicon on insulator (SOI), silicon on sapphire (SOS). That is, the substrate 40 may include all the substrates that may perform the gap-fill process and have various pattern structures thereon.

The gaps G1-G5 used herein may refer to one of the pattern structures in the broadest sense. A gap may refer to a certain space where the upper side thereof is exposed by the surrounding pattern structures that define the gap. For example, the gaps G1-G5 may be a recess region having various geometries formed on the surface of the substrate 40, including a shallow trench isolation (STI) region, which is generally used as a device isolation region to define an active region in a semiconductor manufacturing process. In addition, the gaps G1-G5 may also be in the form of a via that penetrates a conductive layer between an insulating layer and another insulating layer, or penetrates an insulating layer between a conductive layer and another conductive layer. In addition, the gaps G1-G5 may be a gap formed by removing a portion of a single or multi-layered specific material layer (not shown) formed on the surface of the substrate 40 by etching. The material layer (not shown) may include, for example, a conductive material, an insulating material, a semiconductor material, or the like. Furthermore, the gaps G1-G5 may have a cylindrical shape, but the cross-sectional shape of the surface of the gaps G1-G5 may have various polygonal shapes, such as an elliptical, triangular, rectangular, or pentagon, and the like. In addition, the gaps G1-G5 may have an island shape having various surface cross-sectional shapes, but in some embodiments, the gaps G1-G5 may have a line shape on the substrate 40. Furthermore, the gaps G1-G5 may have a vertical profile having substantially the same width from the upper region of the gaps G1-G5, which is the inlet region of the gaps G1-G5, to the lower region thereof. In some embodiments, the gaps G1-G5 may have a non-vertical profile in which the width of the gaps G1-G5 may increase or decrease linearly or stepwise from the upper region of the gap to the lower region thereof.

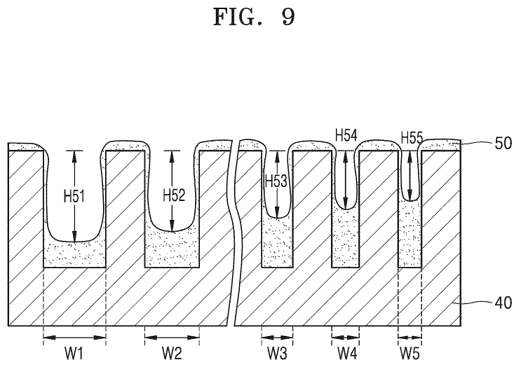

Although FIG. 8 shows a case in which the gaps G1-G5 are formed on the substrate 40 itself, the substrate herein may refer purely to only the substrate 40, or may refer to a substrate having various geometric surfaces before a flowable film 50 shown in FIG. 9 is formed thereon according to the present disclosure. Alternatively, the gaps G1-G5 may be structures formed by etching a portion of a film deposited on a parallel flat substrate.

Subsequently, referring to FIG. 9 together with FIG. 7, the flowable film 50 may be formed on the exposed surface of the substrate 40 having the gaps G1-G5. The flowable film 50 may include an insulating film having the flowable properties, for example a nitride film, an oxide film, or an oxynitride film, etc.. When the RF power is applied to the reaction space while supplying the precursor (e.g., the silicon precursor) and the reactant gas to the reaction space, the reaction space may become a plasma environment, and under the plasma environment, the flowable film 30, such as silicon nitride, may be deposited on the exposed surface of the substrate 40 having the gaps G1-G5, through a condensation reaction, an oligomerization reaction, a polymerization reaction, etc. between the silicon precursor and the reactant gas.

The reaction space may be a reaction chamber that may perform a substrate processing process according to the example embodiments of the present disclosure. Specifically, the reaction space may be a plasma reaction chamber in which example embodiments of the present disclosure may be performed. In some embodiments, the reaction space may be a direct plasma reaction chamber that may generate plasma directly near the upper surface of the substrate 40. In addition, in other embodiments, the reaction space may be a remote plasma chamber.

On the other hand, as the precursor supplied to the reaction space, a silicon-containing precursor may be used. For example, as a Si precursor source, but is not limited thereto, at least one of amino-silane series, iodosilane series, silicon halide series, and an oligomer Si source may be used. For example, the Si source may include at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂ (NEt₂)₂; BDMAS, SiH₂ (NMe₂)₂; BTBAS, SiH₂ (NHtBu)₂; BITS, SiH₂ (NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂ (NHEt)₆; TEAS, Si(NHEt)₄; Si₃H₈; DCS, SiH₂Cl₂; SiHl₃; SiH₂I₂; Dimer-trisilylamine; Trimer-trisilylamine; Tetramer-trisilylamine; Pentamer-trisilylamine; Hexamer-trisilylamine; Heptamer-trisilylamine; and Octamer-trisilylamine, or at least one of its derivatives or mixtures thereof. The reactant gas may include, for example, nitrogen-containing gases. The nitrogen containing gases may include, but are not limited thereto, at least one selected from N₂,N₂O, NO₂, NH₃, N₂H₂, N₂H₄, at least one of radicals thereof, and mixtures thereof. The precursor and the reactant gas may be supplied with an argon gas as a carrier gas.

The flowable film 50 may be deposited under the plasma atmosphere generated by applying the RF power to the reaction space while supplying the precursor and the reactant gas to the reaction space. The deposition step of the flowable film 50 may be performed substantially at the same step as a step of supplying the precursor and the reactant gas to the reaction space.

On the other hand, in FIG. 9, the vertical profile of the flowable film 50 formed on the side wall of the gaps G1-G5 is not clearly illustrated due to a limitation of the scale, but due to the flowable properties of the flowable film 50, the flowable film 50 may flow down from the upper region of the gap to the lower region thereof. Accordingly, the horizontal width of the inner space between the flowable films 50 deposited in the gaps G1-G5 may be determined by a bottom-up filling method in which the width in the lower region of the gap is less than the width in the upper region thereof.

The flowable film 50 shown in FIG. 9 may be formed while repeating the cycle including the deposition step and the pumping step shown in FIG. 7 a plurality of times. A deposition step of the flowable film 50 may be performed using, for example, a flowable chemical vapor deposition method, in which a plasma atmosphere may be generated by applying the RF power to the reaction space while supplying the silicon precursor and the reactant gas to the reaction space, and under the plasma atmosphere, the flowable film 50 may be formed as an oligomer is adsorbed on the exposed surface of the substrate 40, through a condensation reaction, an oligomerization reaction and a polymerization reaction between the silicon precursor and the reactant gas. At this time, the flowable film 50 may flow down to the lower region of the gaps G1-G5 due to the flowable properties of the flowable film 50 due to gravity. That is, the flowable film 40 may be formed by any thickness or height on the side walls and bottom surfaces of the gaps G1-G5, as well as the surface of the substrate 40 surrounding the gaps G1-G5.

Comparing FIG. 9 to FIG. 1B described above, since in FIG. 1B, the gaps 12 of the same shape are formed on the surface of the substrate 10, the flowable film 14 formed on the exposed surface of the substrate 10 may be formed while having the same flowable properties and having the same shape. However, since in FIG. 9, the gaps G1-G5 of different shapes are formed on the surface of the substrate 40, the flowable film 50 formed on the exposed surface of the substrate 40 may be formed in different shapes for each gap G1-G5. Specifically, as the deposition process for the flowable film 50 proceeds, the flowable film 50 may be formed by flowing down the lower regions of the gaps G1-G5 along the side walls of the gaps G1-G5, so the flowable film 50 may be filled upwardly from the bottom surface of the gaps to the upper regions of the gaps G1-G5. At this time, as shown in FIG. 9, the filling speed of the flowable film 50 formed in the gaps G1-G5 may vary depending on the widths of the gaps, that is, the cross-sectional diameters of the gaps. That is, as the cross-sectional diameter of the gap decreases, the influence of the capillary phenomenon may be great, so the filling speed at which the gap is filled with the flowable film 50, or the filling height of the flowable film 50 to which the flowable film 50 is deposited upwardly from the bottom surface of the gaps G1-G5, may increase. FIGS. 8 and 9, the filling heights of the flowable film 50 to be filled the gaps G1-G5 may be values obtained by subtracting depths H51, H52, H53, H54, and H55 of unfilled portions which are not filled with the flowable film 50, respectively, from the vertical depth H5 of the gaps G1-G5 before the flowable film 50 is filled. Therefore, as the horizontal widths of the gaps decrease from the gap G1 to the gap G5 (i.e., W1>W2>W3>W4>W5), the depths of the unfilled portions may also decrease (i.e., H51>H52>H53>H54>H55).

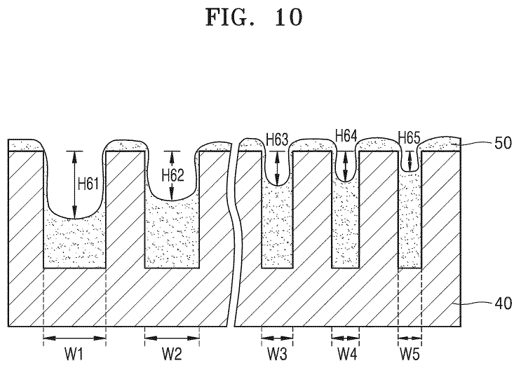

Referring to FIG. 10, when the gap-fill process continues while repeating the cycle including the deposition step and the pumping step in the plurality of times, the flowable film 50 may be continuously deposited on the surface of the substrate 40. As the deposition process for the flowable film 50 proceeds, due to the flowable properties of the flowable film 50, the flowable film 50 may be formed in the gaps G1-G5 while flowing down along the side walls of the gap G1-G5 from the upper region of the gaps G1-G5 to the lower region thereof. Therefore, the filling height of the flowable film 50 filled in the gaps G1-G5 may gradually increase.

On the other hand, in FIGS. 4 and 5, as the cross-sectional diameter of the gaps G1-G5 becomes smaller, capillary condensation strongly occurs in the gap, and thus a gap-fill speed becomes faster. Accordingly, the filling speed of the flowable film 30 to be filled in the gap may also become faster from the gap G1 to the gap G5. In addition, as the cross-sectional diameter of the gap decreases, the filling height of the flowable film 30 to be deposited from the bottom surface of the gaps G1-G5 may also increase.

On the other hand, in FIGS. 9 and 10, as the cross-sectional diameter of the gaps G1-G5 becomes smaller, the filling speed of the flowable film 50 to be filled in the gaps G1-G5 may also become faster from the gap G1 to the gap G5 as in FIGS. 4 and 5, but may become relatively slower compared to FIGS. 4 and 5 (e.g., H23<H53, H24<H54, H25<H55). This is due to the difference between the substrate processing method of FIG. 2 for performing the process shown in FIGS. 4 and 5 and the substrate processing method of FIG. 7 for performing the process shown in FIGS. 9 and 10. In FIG. 2, the precursor as a source gas and the reactant gas are continuously supplied while the pumping step (or exhaust step) is continuously performed, but in FIG. 7, the source gas and the reactant gas may be discontinuously or intermittently supplied while the pumping step is performed continuously.

The flowable gap-fill process may proceed with the oligomerization of a film by the capillary phenomenon by partial pressures of the source gas and the reactant gas within the gap. As the width of the gap decreases, the partial pressures in the gap may increase and the capillary condensation may become stronger, thereby increasing the oligomerization and the gap-fill speed of the film. However, the strengthening of the pumping operation may serve to relieve the partial pressures of the source gas and the reactant gas, and as the width of the gap decreases, the effect of the pumping operation to relieve the partial pressures and decrease a gap-fill speed may increase. Therefore, when the pumping operation is continuously performed while blocking the supply of the source gas and the reactant gas, as shown in FIG. 7, the pumping efficiency may increase in the reaction space, and therefore as the width of the gap decreases, the effect of the pumping operation to relieve the partial pressures and decrease a gap-fill speed may increase. That is, when only the pumping step (or exhaust step) is performed, as the cross-sectional diameter of the gap decreases, the increase speed of the filling height of the flowable film 50 to be deposited upwardly from the bottom surface of the gaps G1-G5 may become relatively smaller and the difference between the filling heights of the flowable film in the gaps G1-G5 may decrease (i.e., A (H52-H53)<A (H22-H23)).

Herein, the ‘filling speed of the flowable film’ refers to a rate of change of filling volume of the flowable film filled in a gap having a specific volume, and the ‘rate of increase of the filling height of the flowable film’ refers to a rate of change of filling height of the flowable film to be filled upwardly from the bottom surface of the gap.

On the other hand, ‘the filling speed of the flowable film is relatively slower (or faster)’ may include both the following meanings.

First, based on the same process time, for example, in the gap (e.g., G1) with a relatively large cross-sectional diameter of the gap, it means that the filling speed of the flowable film 50 in FIGS. 9 and 10 is relatively faster than that of the flowable film 30 in FIGS. 4 and 5. That is, it means that the filling speed of the flowable film 50 in the gap G1 according to the process sequence of FIG. 7 is relatively compared to the filling speed of the flowable film 30 in the gap G1 according to the process sequence of FIG. 2. In the same sense, based on the same process time, for example, in the gap (e.g., G5) with a relatively small cross-sectional diameter of the gap, it means that the filling speed of the flowable film 50 in FIGS. 9 and 10 is relatively slower than that of the flowable film 30 in FIGS. 4 and 5. That is, it means that the filling speed of the flowable film 50 in the gap G1 or G5 according to the process sequence of FIG. 7 is relatively compared to the filling speed of the flowable film 30 in the gap G1 or G5 according to the process sequence of FIG. 2.

Therefore, from the results of FIGS. 4 and 5, and from FIGS. 9 and 10, it may be seen that the filling speed of the flowable film 50 formed according to the process sequence of FIG. 7 in the gap G1 may be relatively faster than that of the flowable film 30 formed according to the process sequence of FIG. 2 in the gap G1, however, the filling speed of the flowable film 50 formed according to the process sequence of FIG. 7 in the gap G5 may be relatively slower than that of the flowable film 30 formed according to the process sequence of FIG. 2 in the gap G5.

Second, referring to FIGS. 9 and 10, based on the same process time, it means that for example, the filling speed of the flowable film 50 in the gap G1 where the cross-sectional diameter of the gap is relatively large is relatively slower (or faster) than any first reference filling speed that is an arbitrary reference in the gap G1 in the gap-fill process according to the present disclosure, and the filling speed of the flowable film 50 in the gap G5 where the cross-sectional diameter of the gap is relatively small is relatively slower (or faster) than any second reference filling speed that is another arbitrary reference in the gap G5 in the gap-fill process according to the present disclosure. That is, it means that according to the process sequence of FIG. 7, the degree to which the filling speed of the flowable film 50 in the gap G1 is slower (or faster) than the first reference filling speed is relatively compared to the degree to which the filling speed of the flowable film 50 in the gap G5 is slower (or faster) than the second reference filling speed. According to example embodiments of the present disclosure, in order to reduce the difference in the filling speed of the flowable film between the filling speed of the flowable film 50 in the gap G1 having a relatively large cross-sectional diameter and the filling speed of the flowable film 50 in the gap G5 having a relatively small cross-sectional diameter, the filling speed of the flowable film 50 in the gap G1 may be relatively fast while at the same time the filling speed of the flowable film 50 in the gap G5 may be relatively slow. Therefore, when the gap-fill process is performed on the substrate having gaps having various cross-sectional diameters formed on the surface thereof, the difference in filling speed of the flowable film between the various gaps may be reduced, thereby reducing process errors in the gap-fill process, shortening the process time of the gap-fill process, and also reducing the over-deposition of the flowable film as a gap-fill material.

On the other hand, ‘the rate of increase of the filling height of the flowable film is relatively slower (or faster)’ may include both the following meanings.

First, based on the same process time, for example, in the gap (e.g., G1) with a relatively large cross-sectional diameter of the gap, it means that the rate of increase (i.e., (H61-H51)/time) of the filling height of the flowable film 50 to be formed according to the process sequence of FIG. 7 as shown in FIGS. 9 and 10 is relatively slower (or faster) than the rate of increase (i.e., (H21-H11)/time) of the filling height of the flowable film 30 to be formed according to the process sequence of FIG. 2 as shown in FIGS. 4 and 5. That is, it means that the rate of increase (i.e., (H61-H51)/time) of the filling height of the flowable film 50 to be formed according to the process sequence of FIG. 7 is relatively compared to the rate of increase (i.e., (H21-H11)/time) of the filling height of the flowable film 30 to be formed according to the process sequence of FIG. 2. In the same sense, based on the same process time, for example, in the gap (e.g., G5) with a relatively small cross-sectional diameter of the gap, it means that the rate of increase (i.e., (H65-H55)/time) of the filling height of the flowable film 50 to be formed according to the process sequence of FIG. 7 as shown in FIGS. 9 and 10 is relatively slower (or faster) than the rate of increase (i.e., (H25-H15)/time) of the filling height of the flowable film 30 to be formed according to the process sequence of FIG. 2 as shown in FIGS. 4 and 5. That is, it means that the rate of increase of the filling height of the flowable film 50 in the gap G1 or G5 according to the process sequence of FIG. 7 is relatively compared to the rate of increase of the filling height of the flowable film 30 in the gap G1 or G5 according to the process sequence of FIG. 2.

Therefore, from the results of FIGS. 4 and 5, and from FIGS. 9 and 10, it may be seen that the rate of increase of the filling height of the flowable film 50 formed according to the process sequence of FIG. 7 in the gap G1 may be relatively faster than that of the flowable film 30 formed according to the process sequence of FIG. 2 in the gap G1, however, the rate of increase of the filling height of the flowable film 50 formed according to the process sequence of FIG. 7 in the gap G5 may be relatively slower than that of the flowable film 30 formed according to the process sequence of FIG. 2 in the gap G5.

Second, referring to FIGS. 9 and 10, based on the same process time, it means that for example, the rate of increase of the filling height of the flowable film 50 in the gap G1 where the cross-sectional diameter of the gap is relatively large is relatively slower (or faster) than any first reference increase rate of the filling height that is an arbitrary reference in the gap G1 in the gap-fill process according to the present disclosure, and the rate of increase of the filling height of the flowable film 50 in the gap G5 where the cross-sectional diameter of the gap is relatively small is relatively slower (or faster) than any second reference increase rate of the filling height that is another arbitrary reference in the gap G5 in the gap-fill process according to the present disclosure. That is, it means that according to the process sequence of FIG. 7, the degree to which the rate of increase of the filling height of the flowable film 50 in the gap G1 is slower (or faster) than the first reference increase rate of the filling height is relatively compared to the degree to which the rate of increase of the filling height of the flowable film 50 in the gap G5 is slower (or faster) than the second reference increase rate of the filling height. According to example embodiments of the present disclosure, in order to reduce the difference in the increase rate of the filling height of the flowable film between the increase rate of the filling height of the flowable film 50 in the gap G1 having a relatively large cross-sectional diameter and the increase rate of the filling height of the flowable film 50 in the gap G5 having a relatively small cross-sectional diameter, the increase rate of the filling height of the flowable film 50 in the gap G1 may be relatively fast while at the same time the increase rate of the filling height of the flowable film 50 in the gap G5 may be relatively slow. Therefore, when the gap-fill process is performed on the substrate having gaps having various cross-sectional diameters formed on the surface thereof, the difference in increase rate of the filling height of the flowable film between the various gaps may be reduced, thereby reducing process errors in the gap-fill process, shortening the process time of the gap-fill process, and also reducing the over-deposition of the flowable film as the gap-fill material.

Referring again to FIG. 7 described above together with FIGS. 9 and 10, when the gap is filled with the flowable film with respect to the substrate in which the gap having a relatively large cross-sectional diameter of the gap (or a pattern having a relatively wide CD) and the gap having a relatively small cross-sectional diameter of the gap (or a pattern having a relatively narrow CD) coexist on the surface thereof, the smaller the cross-sectional diameter of the gap, the greater the influence of capillary adsorption. In the gap-fill process of a flowable film, the precursor and the reactant gas are subject to the condensation reaction under the plasma atmosphere to generate an oligomer, and the resulting oligomer is adsorbed and deposited on the exposed surface of the substrate. At this time, the generation of oligomer may be further accelerated as the partial pressures of the precursor and the reactant gas increase. Therefore, in the gap with a relatively small cross-sectional diameter, the partial pressures of the precursor and the reactant gas are relatively high, so the generation of oligomer may be rapidly progressed and the gap-fill process may be completed relatively quickly. On the other hand, in the gap with a relatively large cross-sectional diameter, the partial pressures of the precursor and the reactant gas are relatively low, so the oligomer may not be actively generated and the gap-fill process may be completed relatively slowly. However, when only the pumping operation (or exhaust operation) is performed, the partial pressure may be relieved more effectively, thereby reducing the difference in filling height between the gaps having different widths and improving the uniformity of the filling height.

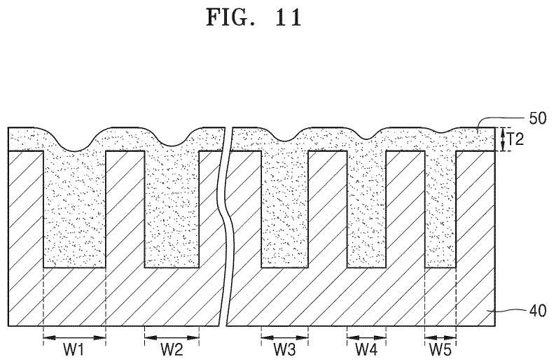

Referring to FIG. 11, the deposition process of the flowable film 50 may be terminated. The deposition process of the flowable film 50 may be terminated based on the gap in which the flowable film 50 is filled at least last, for example. In FIG. 11, for example, when the flowable film 50 fully fills the gap G1 that has the largest width of a gap (i.e., the largest cross-sectional diameter), the deposition process may be terminated. Therefore, since the deposition process of the flowable film 50 may continue until the filling of the flowable film 50 in the gap G1 is fully completed, as the width of the gap becomes smaller from the gap G1 to the gap G5, the flowable film 50 may be over-deposited over the gap, for example, by a portion corresponding to a thickness T2.

However, compared to the case of FIG. 6, in the case of FIG. 11, the difference in the relative filling speed of the flowable film between the gap G1 and the gap G5 has been reduced, or the difference in the relative increase rate of the filling height of the flowable film between the gap G1 and the gap G5 has been reduced. Therefore, the process time between the filling completion time in the gap G5 and the filling completion time in the gap G1 may be shortened. Since this has the technical benefit of shortening the process time, the over-deposition of the flowable film may be relatively reduced accordingly. That is, when the gap-fill process is terminated, a thickness T2 of the over-deposited flowable film 50 in FIG. 11 which is deposited according to FIG. 7 may be reduced compared to the thickness T1 of the over-deposited flowable film 30 in FIG. 6 which is deposited according to FIG. 2 (i.e., T2<T1).

As described above, according to example embodiments of the present disclosure, by periodically adding the pumping step in the deposition step, the difference in partial pressures due to the difference in the pattern structures in the reaction space may be adjusted, and the influence of the capillary phenomenon may be relieved. Therefore, when the gap-fill process according to example embodiments of the present disclosure is performed on the substrate in which gaps having various cross-sectional diameters, or various internal volume are formed on the surface thereof, the difference in the filling speed of the flowable film or in the increase rate of the filling height of the flowable film between the various gaps may be reduced, thereby reducing the deviation of gap-fill efficiency. In addition, when the end of the gap-fill process is set based on the degree of filling in the gap having the largest cross-sectional diameter or the largest internal volume, the difference in the filling speed between the gap having the largest cross-sectional diameter or the largest internal volume and the gap having the smallest cross-sectional diameter or the smallest internal volume may be reduced, so the process time of the gap-fill process may be shortened. In addition, along with the shortening of the process time of the gap-fill process, the over-deposition of the flowable film as the gap-fill material may be reduced around the gap having the smallest cross-sectional diameter or the smallest internal volume. Therefore, the process time of an etch-back process or a chemical mechanical polishing process for removing the over-deposited flowable film may be shortened, and furthermore, the consumption of the over-deposited flowable film may be reduced.

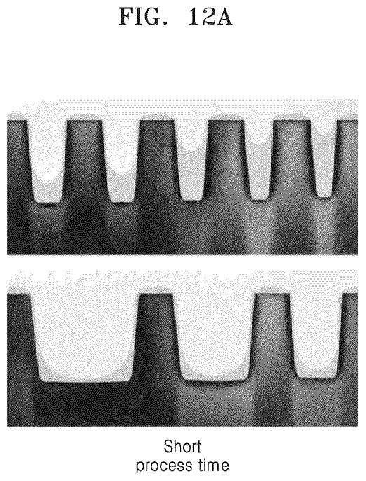

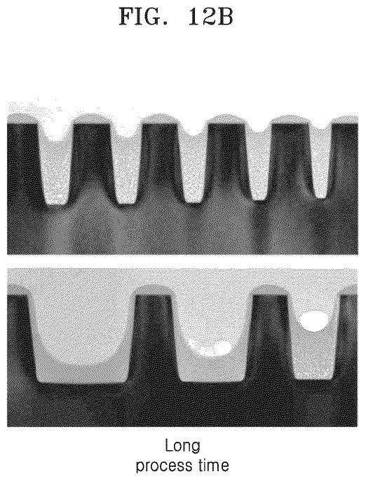

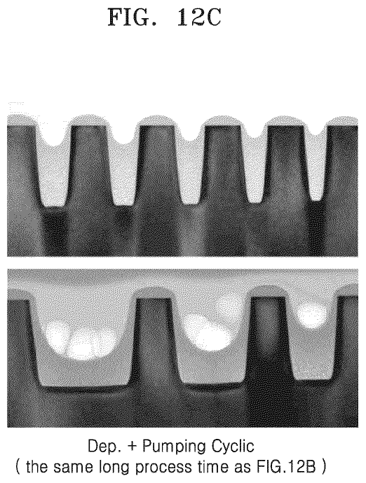

FIG. 12A is a TEM photograph illustrating a flowable film formed in a gap relatively for a short time according to the process sequence of FIG. 2, and FIG. 12B is a TEM photograph illustrating a flowable film formed in a gap relatively for a long time according to the process sequence of FIG. 2. FIG. 12C is a TEM photograph illustrating a flowable film formed in a gap according to the process sequence of FIG. 7. FIG. 12A is a photograph of the result of performing the gap-fill process according to the process sequence of FIG. 2 for tens of seconds to hundreds of seconds, for example, for about 100 seconds to about 300 seconds, and FIG. 12B is a photograph of the result of performing the gap-fill process according to the process sequence of FIG. 2 for tens of seconds to hundreds of seconds, for example, for about 300 seconds to about 700 seconds. FIG. 12C is a photograph of the result of repeating the cycle according to the process sequence of FIG. 7 several to several tens of times, for example, about 2 to about 50 times, in which the cycle includes the deposition step for tens of seconds to hundreds of seconds, such as about 10 seconds to about 200 seconds, and the pumping step for tens of seconds to hundreds of seconds, such as about 10 seconds to about 200 seconds.

FIG. 12C is the TEM photograph after performing the gap-fill process by supplying the source gas and the reactant gas for approximately the same process time as that of FIG. 12B, except for the time of the pumping step. In the case of FIGS. 12A and 12B, in which the gap-fill process was performed according to the substrate processing method of FIG. 2, the filling height of the flowable film as the gap-fill material increases rapidly in a narrow CD gap, whereas in a wide CD gap, the filling height of the flowable film increase relatively slowly.

In addition, comparing FIGS. 12B and 12C, even when the gap-fill process is performed for the same process time, in the case of FIG. 12C, the filling height of the flowable film in the narrow CD gap increases relatively slowly compared to the case of FIG. 12B, while the filling height of the flowable film in the wide CD gap increases relatively rapidly compared to the case of FIG. 12B. Accordingly, according to the substrate processing method of FIG. 7 including a step in which only the pumping step is performed, since the increase rate of filling height of the flowable film in the relatively wide CD gap is relatively greater than that of the flowable film in the relatively narrow CD gap, the difference in the increase rate of the filling height of the flowable film between the wide CD gap and the narrow CD gap may decrease, thereby shortening the process time in the gap-fill process. That is, in the substrate processing method according to FIG. 7, the pumping effect of reducing the partial pressure of the source gas and the reactant gas in the narrow gap may be greater than in the wide gap. Accordingly, since the increase rate of the filling height of the flowable film in the relatively narrow CD gap is relatively less than that of the flowable film in the relatively wide CD gap, the difference in the filling height of the flowable film between the wide CD gap and the narrow CD gap may decrease.

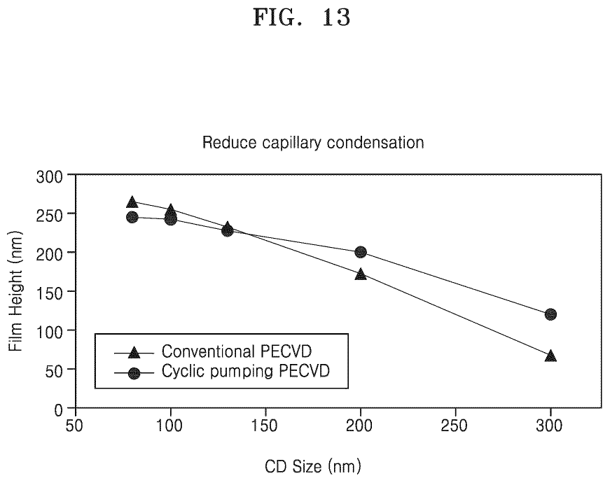

FIG. 13 is a graph comparing the height of the flowable film formed in a gap for each CD size according to example embodiments of the present disclosure, to that of the prior art.

Referring to FIG. 13, a horizontal axis of FIG. 13 represents the size of the pattern, that is, the CD size and a vertical axis thereof represents the height of the flowable film filled in the gap. In both the gap-fill process according to the conventional PECVD process and the gap-fill process according to a periodic pumping PECVD process of the present disclosure, as the CD size increases, that is, the width of the gap increases, the capillary adsorption decreases, the filling speed of the flowable film decreases, and the filling height of the flowable film decreases. However, according to the present disclosure, it may be seen that the height of the flowable film decreased by about 10% compared to the result according to the conventional PECVD process at a position of a narrow CD size, for example, about 80 nm, and the height of the flowable film increased by about 2 times compared to the result according to the conventional PECVD process at a position of a wide CD size, for example, about 300 nm.

Therefore, according to the substrate processing method of FIG. 7, it may be seen that since the increase rate of the filling height of flowable film is relatively fast in the relatively wide CD gap, and the increase rate of the filling height of flowable film is relatively slow in the relatively narrow CD gap, the difference in the increase rate of the filling height may decrease, and therefore the process time of the gap-fill process may be shortened. That is, when the pumping step without supplying the source gas and the reactant gas is periodically repeated, the capillary adsorption and the increase rate of the filling height of the flowable film may decrease in a narrow gap structure, thereby further improving the uniformity of the filling height of the flowable film between the gap structures.

It will be obvious by those of ordinary skill in the art that the present disclosure described above is not limited to the above-described embodiments and accompanying drawings, and that various substitutions, modifications, and changes are possible without departing from the scope and sprit of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of processing a substrate, the method comprising:
providing a substrate in a reaction space, wherein a first gap having a first cross-sectional diameter in a horizontal direction, and a second gap having a second cross-sectional diameter in the horizontal direction are formed on a surface of the substrate, wherein the second cross-sectional diameter is less than the first cross-sectional diameter; and
filling the first gap and the second gap with a flowable film while supplying a precursor and a reactant gas to the reaction space,
the filling comprising:
supplying the precursor and the reactant gas to the reaction space; and
pumping the reaction space,
wherein, by repeatedly performing the supplying and the pumping, in order to decrease a height difference between a filling height of the flowable film filled in the first gap and a filling height of the flowable film filled in the second gap, a rate of increase of the filling height of the flowable film in the first gap increases relatively, and at the same time, the rate of increase of the filling height of the flowable film in the second gap decreases relatively.

2. The method of processing a substrate of claim 1, wherein, in the pumping the reaction space, the supply of the precursor and the reactant gas is blocked, and the supply of RF power applied to the reaction space is blocked.

3. The method of processing a substrate of claim 1, wherein the reaction space is continuously pumped even in the supplying the precursor and the reactant gas.

4. The method of processing a substrate of claim 1, wherein a ratio of a period of the supplying the precursor and the reactant gas to a period of the pumping the reaction space is in a range between about 1:5 to about 5:1.

5. The method of processing a substrate of claim 1, wherein, by repeatedly performing the supplying the precursor and the reactant gas and the pumping the reaction space, in order to decrease a difference between a filling speed of the flowable film filled in the first gap and a filling speed of the flowable film filled in the second gap, the filling speed of the flowable film in the first gap increases relatively, and at the same time, the filling speed of the flowable film in the second gap decreases relatively.

6. The method of processing a substrate of claim 1, wherein an internal volume of the first gap is greater than an internal volume of the second gap.

7. The method of processing a substrate of claim 1, wherein pressure within the reaction space in the supplying the precursor and the reactant gas is in a range of about 1 Torr to about 10 Torr, and pressure within the reaction space in the pumping is less than or equal to about 3 Torr.

8. The method of processing a substrate of claim 1, wherein the pumping is performed to decrease a difference between partial pressure in the first gap and partial pressure in the second gap.

9. The method of processing a substrate of claim 1, wherein the filling is performed at a process temperature between about 0° C. and about 150° C.

10. The method of processing a substrate of claim 1, wherein the precursor supplied to the reaction space comprises a silicon-containing precursor and the reactant gas comprises a nitrogen-containing gas.

11. The method of processing a substrate of claim 10, wherein the silicon precursor comprises at least one of amino-silane series, iodosilane series, silicon halide series, and oligomer Si source, or at least one of mixtures thereof.

12. The method of processing a substrate of claim 10, wherein the silicon precursor comprises at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DTBAS, SiH₃N(tBu)₂; BDEAS, SiH₂ (NEt₂)₂;
BDMAS, SiH₂ (NMe₂)₂; BTBAS, SiH₂ (NHtBu)₂; BITS, SiH₂ (NHSiMe₃)₂; DIPAS, SiH₃N(iPr)₂; TEOS, Si(OEt)₄; SiCl₄; HCD, Si₂Cl₆; 3DMAS, SiH(N(Me)₂)₃; BEMAS, SiH₂[N(Et)(Me)]₂; AHEAD, Si₂(NHEt)₆;
TEAS, Si(NHEt)₄; Si₃H₈; DCS, SiH₂Cl₂; SiHl₃; SiH₂I₂; Dimer-trisilylamine; Trimer-trisilylamine;
Tetramer-trisilylamine; Pentamer-trisilylamine; Hexamer-trisilylamine; Heptamer-trisilylamine;
and Octamer-trisilylamine, or at least one of derivatives thereof or mixtures thereof.

13. A method of processing a substrate, the method comprising:
providing a substrate to a reaction space, the substrate having at least two gaps in a surface of the substrate; and
depositing a flowable film in the at least two gaps while supplying a precursor and a reactant gas to the reaction space,
wherein the depositing a flowable film is discontinuously performed while a pumping operation for the reaction space is continuously maintained.

14. The method of processing a substrate of claim 13, wherein, during a discontinuous period of the depositing, the supply of the precursor and the reactant gas to the reaction space is blocked, and the supply of RF power applied to the reaction space is blocked.

15. The method of processing a substrate of claim 13, wherein
the at least two gaps comprise a first gap having a first cross-sectional diameter in a horizontal direction, and a second gap having a second cross-sectional diameter in the horizontal direction, wherein the second cross-sectional diameter is less than the first cross-sectional diameter, and
as the depositing is discontinuously performed, in order to decrease a height difference between a filling height of the flowable film filled in the first gap and a filling height of the flowable film filled in the second gap, a rate of increase of the filling height of the flowable film in the first gap increases relatively, and at the same time, the rate of increase of the filling height of the flowable film in the second gap decreases relatively.

16. The method of processing a substrate of claim 13, wherein
the at least two gaps comprise a first gap having a first cross-sectional diameter in a horizontal direction, and a second gap having a second cross-sectional diameter in the horizontal direction, wherein the second cross-sectional diameter is less than the first cross-sectional diameter, and
as the depositing is discontinuously performed, in order to decrease a difference between a filling speed of the flowable film filled in the first gap and a filling speed of the flowable film filled in the second gap, the filling speed of the flowable film in the first gap increases relatively, and at the same time, the filling speed of the flowable film in the second gap decreases relatively.

17. The method of processing a substrate of claim 16, wherein an internal volume of the first gap is greater than an internal volume of the second gap.

18. The method of processing a substrate of claim 13, wherein pressure within the reaction space in the depositing is in a range of about 1 Torr to about 10 Torr, and pressure within the reaction space during a discontinuous period of the depositing is less than or equal to about 3 Torr.

19. The method of processing a substrate of claim 13, wherein the precursor supplied to the reaction space comprises a silicon-containing precursor and the reactant gas comprises a nitrogen-containing gas.

20. A method of processing a substrate, the method comprising:
providing a substrate having at least two gaps formed on a surface of the substrate in a reaction space, wherein the at least two gaps comprise a first gap having a first cross-sectional diameter in a horizontal direction, and a second gap having a second cross-sectional diameter in the horizontal direction, wherein the second cross-sectional diameter is less than the first cross-sectional diameter;
depositing a flowable film in the least two gaps while supplying a precursor and a reactant gas to the reaction space; and
performing a pumping operation for the reaction space,
wherein the depositing the flowable film and the performing the pumping operation are repeatedly performed in one cycle, and as the number of repetitions of the cycle increases, a difference between a filling speed of the flowable film to be filled in the first gap and a filling speed of the flowable film to be filled in the second gap decreases.

21. The method of processing a substrate of claim 20, wherein, in the performing the pumping operation, the supply of the precursor and the reactant gas to the reaction space is blocked, and the supply of RF power applied to the reaction space is blocked.

22. The method of processing a substrate of claim 20, wherein the depositing the flowable film and the performing the pumping operation are repeatedly performed in one cycle, and as the number of repetitions of the cycle increases, in order to decrease a height difference between a filling height of the flowable film filled in the first gap and a filling height of the flowable film filled in the second gap, a rate of increase of the filling height of the flowable film in the first gap increases relatively, and at the same time, the rate of increase of the filling height of the flowable film in the second gap decreases relatively.

23. The method of processing a substrate of claim 20, wherein an internal volume of the first gap is greater than an internal volume of the second gap.

24. The method of processing a substrate of claim 20, wherein pressure within the reaction space in the depositing the flowable film is in a range of about 1 Torr to about 10 Torr, and pressure within the reaction space in the performing the pumping operation is less than or equal to about 3 Torr.
